(19) United States
(12) Patent Application Publication
(10) Pub. No.: US 2026/0075836 A1
(43) Pub. Date: Mar. 12, 2026

(54) SUPPORTED CAPACITOR ELECTRODE STRUCTURE FOR MEMORY DEVICE

(71) Applicant: Micron Technology, Inc., Boise, ID (US)

(72) Inventors: Richard BEELER, Boise, ID (US); Sarah BULL, Boise, ID (US); Sushant MAHAT, Boise, ID (US); Christopher W. PETZ, Boise, ID (US)

(21) Appl. No.: 19/266,893

(22) Filed: Jul. 11, 2025

Related U.S. Application Data
(60) Provisional application No. 63/691,424, filed on Sep. 6, 2024.

(51) Int. Cl. H10B 53/30

(52) U.S. Cl. CPC H10B 53/30

(57) ABSTRACT

Implementations described herein relate to various structures, integrated assemblies, and memory devices. In some implementations, an integrated assembly includes a support layer of a dielectric material and a pillar structure passing through the support layer. The integrated assembly includes a multi-layer coupling structure between the pillar structure and the support layer that conjoins the pillar structure with the support layer. The multi-layer coupling structure includes an outer layer that conjoins with the support layer and an inner layer that conjoins with the pillar structure, where the outer layer and the inner layer include respective materials that are different from each other.

### CROSS-REFERENCE TO RELATED APPLICATION

This Patent Application claims priority to U.S. Provisional Ser. No. 63/691,424, filed on Sep. 6, 2024, entitled “SUPPORTED CAPACITOR ELECTRODE STRUCTURE FOR MEMORY DEVICE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a supported capacitor electrode structure for a memory device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIG. 2 is a diagrammatic view of an example supported capacitor electrode structure described herein.

FIG. 3 is a flowchart of an example method of forming an integrated assembly or memory device having a supported capacitor electrode structure described herein.

FIGS. 4A-4G are diagrammatic views showing a supported capacitor electrode structure at example stages of an example process of forming the supported capacitor electrode structure.

FIG. 5 is a diagrammatic view of an example memory device.

### DETAILED DESCRIPTION

Dynamic random-access memory (DRAM) is a prevailing technology for electronic devices requiring fast and reliable memory. The fabrication of DRAM cells includes the construction of capacitors with structures capable of high charge storage. However, the formation of the capacitors poses numerous technical challenges.

In some cases, and as an example, manufacturing the capacitors entails manufacturing bottom electrodes of the capacitors from pillar structures. Manufacturing the pillar structures includes using a sacrificial material that is later removed after forming and patterning the pillar structures. A process of sculpting these pillar structures to final critical dimensions without causing defects is delicate and prone to several issues. One of the main hurdles in capacitor fabrication is achieving the precision required to create stable pillar structures without introducing defects during sculpting of the pillar structures.

Some implementations described herein enable the construction of a supported capacitor electrode structure, which is essential for memory operations. For example, a memory cell may comprise a support layer made of a dielectric material, a pillar structure (e.g., an electrode) made of a conductive material passing through the support layer, and a multi-layer coupling structure between the pillar structure and the support layer.

In these ways, a structural integrity and manufacturing efficiency of a memory cell including the supported capacitor electrode structure is enhanced. The multi-layer coupling structure may reduce a risk of detachment between the pillar structure and the support layer, thereby mitigating risks of short-circuiting and improving operational reliability of the memory cell, resulting in optimal resource utilization and contributing to the conservation of processing resources and raw materials. Additionally, the multi-layer coupling structure serves to decrease a likelihood of structural weakness during sculpting of the pillar structure to its final dimensions, ultimately contributing to lower defect rates and higher throughput in semiconductor fabrication.

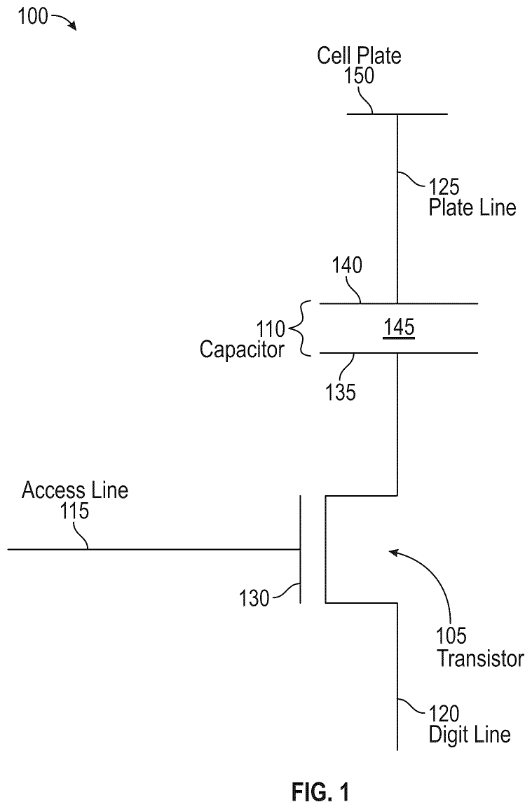

FIG. 1 is a circuit diagram of an example memory cell 100 described herein. In some implementations, the memory cell 100 is a ferroelectric memory cell. Alternatively, the memory cell 100 may be a linear dielectric memory cell, an anti-ferroelectric memory cell, or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

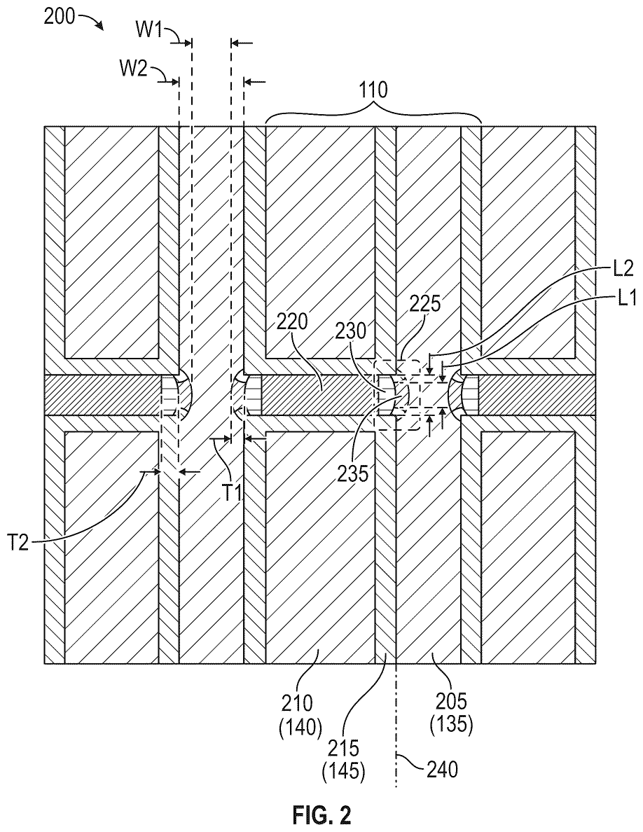

In some implementations, the bottom electrode 135 is a pillar structure included as part of a supported capacitor electrode structure. As described in greater detail in connection with FIGS. 2-4G, the pillar structure is conjoined to a support layer using a multi-layer coupling structure, thereby increasing a stability of the pillar structure during an etching operation that sculpts the pillar structure to its final critical dimension.

As indicated above, FIG. 1 is provided as an example. Other examples may differ from what is described with respect to FIG. 1.

FIG. 2 is a diagrammatic view of an example supported capacitor electrode structure 200 described herein. The diagrammatic view may be a section view of a memory cell (e.g., a section view of the memory cell 100 of FIG. 1) including the supported capacitor electrode structure 200. As shown in FIG. 2, the supported capacitor electrode structure 200 includes a pillar structure 205, a conductive layer 210, an insulator layer 215, a support layer 220, and a multi-layer coupling structure 225.

In some implementations, the pillar structure 205 corresponds to the bottom electrode 135 of the capacitor 110 of FIG. 1. As shown in FIG. 2, the pillar structure 205 may be vertically-oriented. A material included in the pillar structure 205 may be an electrical conductor and may comprise, consist of, or consist essentially of conductive material. The conductive material may comprise, consist of, or consist essentially of titanium nitride. Alternatively, the conductive material may comprise, consist of, or consist essentially of titanium, tungsten, cobalt, nickel, platinum, ruthenium, metal silicide, titanium nitride, titanium silicon, conductively-doped silicon, conductively-doped germanium, conductively-doped gallium arsenide, or another conductive material, among other examples.

In some implementations, the conductive layer 210 corresponds to the top electrode 140 of the capacitor 110 of FIG. 1. A material included in the conductive layer 210 may be an electrical conductor and may comprise, consist of, or consist essentially of conductive material. The conductive material may comprise, consist of, or consist essentially of titanium nitride. Alternatively, the conductive material may comprise, consist of, or consist essentially of titanium, tungsten, cobalt, nickel, platinum, ruthenium, metal silicide, titanium silicon, conductively-doped silicon, conductively-doped germanium, conductively-doped gallium arsenide, or another conductive material, among other examples.

In some implementations, the insulator layer 215 corresponds to the insulator 145 of the capacitor 110 of FIG. 1. A material included in the insulator layer 215 may be an insulator and may comprise, consist of, or consist essentially of a dielectric material. In some implementations, the dielectric material may comprise, consist of, or consist essentially of silicon nitride, silicon oxide, aluminum nitride, zirconium oxide, hafnium oxide, aluminum oxide, yttrium oxide, lanthanum oxide, lutetium oxide, erbium oxide, or another suitable dielectric material. Additionally, or alternatively and in some implementations, the dielectric material may comprise, consist of, or consist essentially of an anti-ferroelectric material such as lead zirconate, silver niobate, bismuth ferrite, or another suitable anti-ferroelectric material.

As shown in FIG. 2, the support layer 220 may be laterally-oriented and the pillar structure 205 may pass through the support layer 220. In some implementations, the support layer 220 may be referred to as a mid-lattice layer. A material included in the support layer 220 may be an insulator and may comprise, consist of, or consist essentially of a dielectric material. In such a case, the dielectric material may comprise, consist of, or consist essentially of silicon nitride. Alternatively, the dielectric material may comprise, consist of, or consist essentially of silicon oxide, aluminum nitride, or another suitable dielectric material, among other examples.

As shown in FIG. 2, the multi-layer coupling structure 225 includes an outer layer 230 and an inner layer 235. The outer layer 230 may conjoin with the support layer 220, and the inner layer 235 may conjoin with the pillar structure 205. Furthermore, the outer layer 230 and the inner layer 235 may conjoin with one another to anchor the pillar structure 205 to the support layer 220.

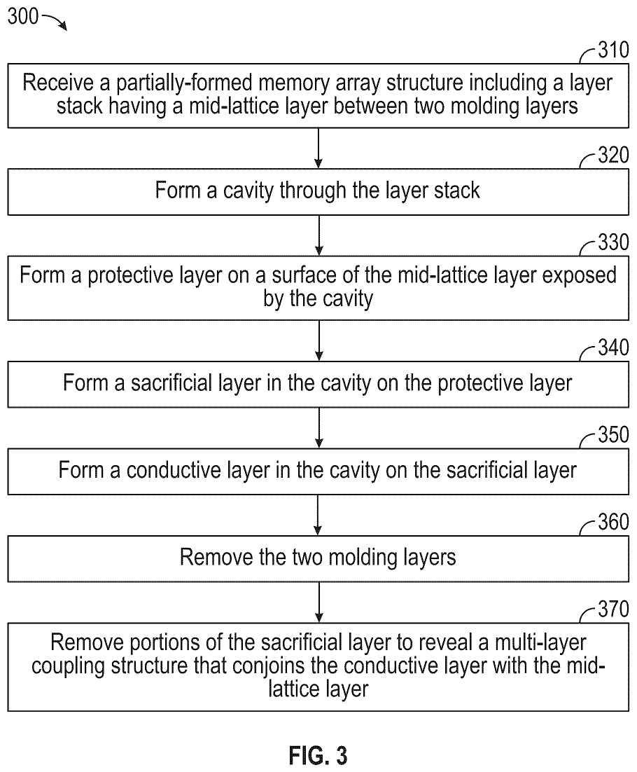

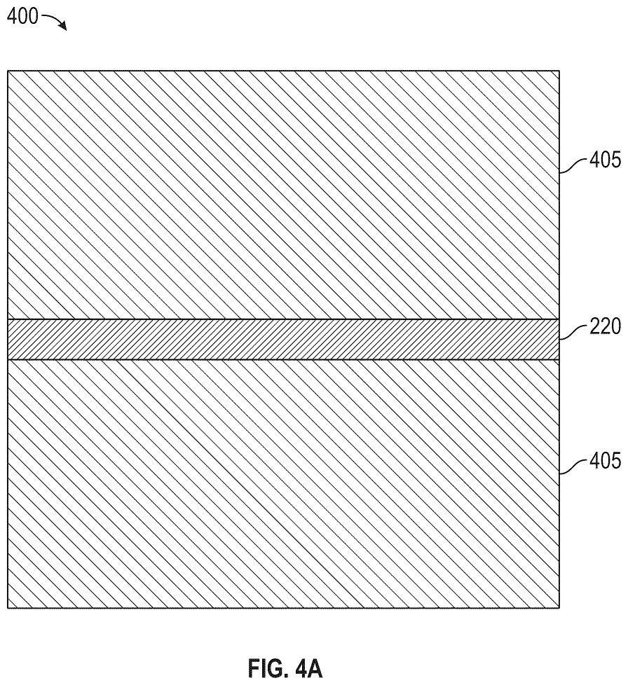

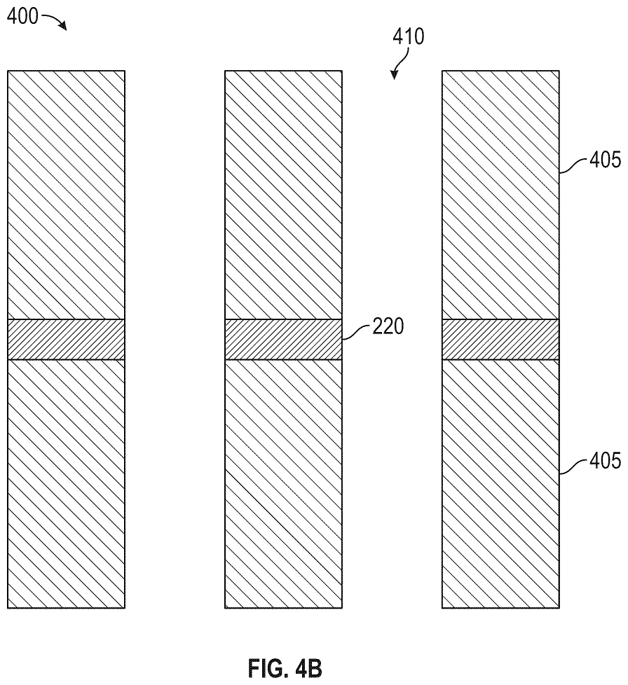

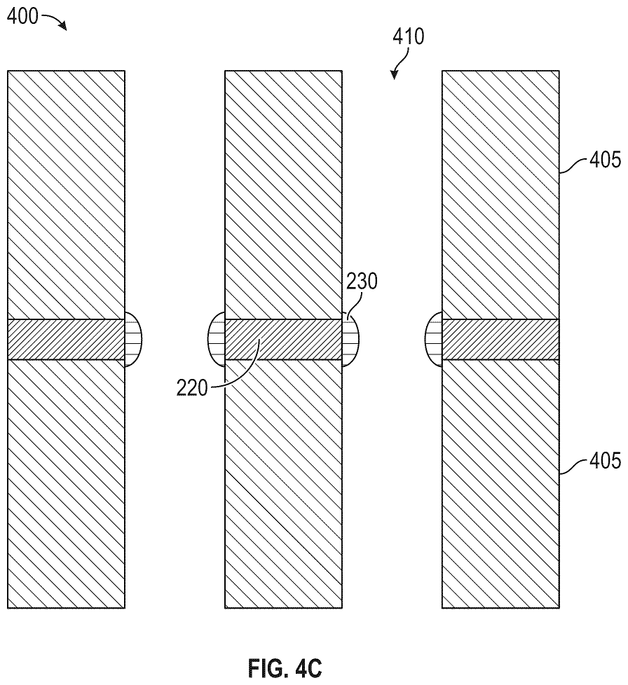

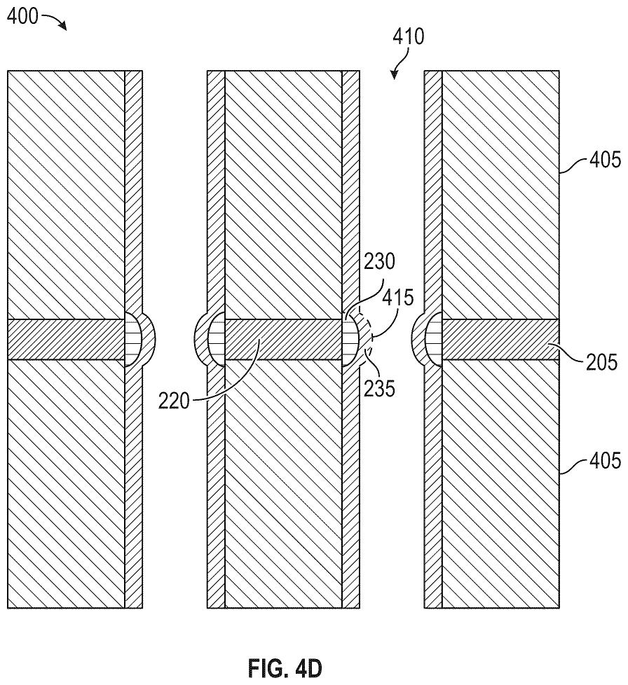

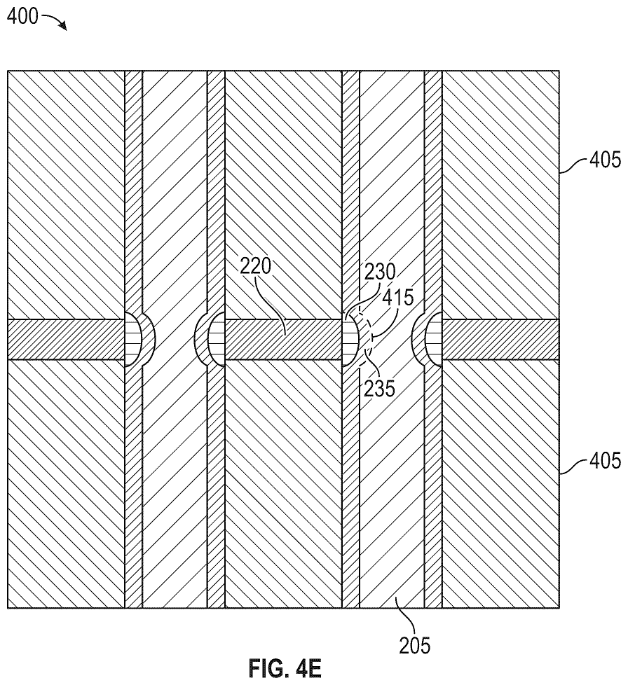

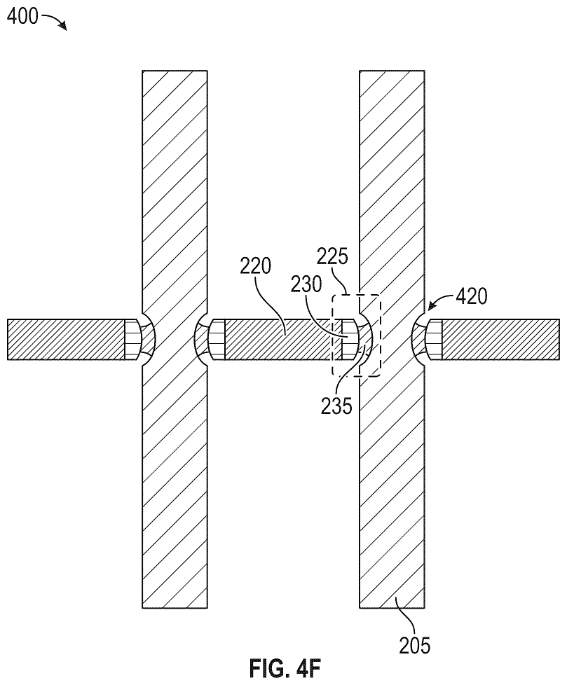

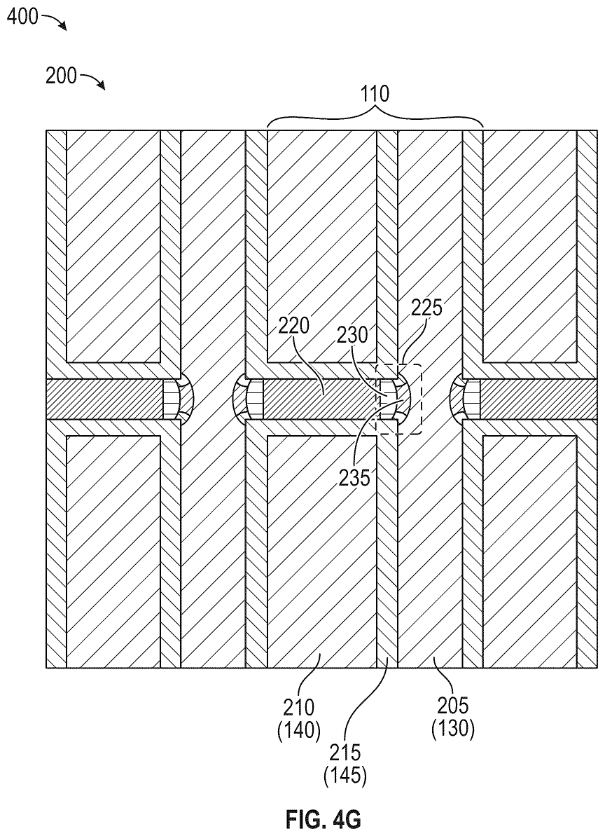

The outer layer 230 may be an electrical conductor and may comprise, consist of, or consist essentially of conductive material. The conductive material may comprise, consist of, or consist essentially of titanium nitride. Alternatively, the conductive material may comprise, consist of, or consist essentially of titanium, tungsten, cobalt, nickel, platinum, ruthenium, metal silicide, titanium silicon, conductively-doped silicon, conductively-doped germanium, conductively-doped gallium arsenide, or another conductive material, among other examples. In some implementations, a conductive material of the outer layer 230 and a conductive material of the pillar structure 205 may be a same conductive material. Alternatively, and in some implementations, a conductive material of the outer layer 230 and a conductive material of the pillar structure 205 may be different conductive materials. In some implementations, and as described in greater detail in connection with FIGS. 3-4G, the outer layer 230 may be used as a protective layer that is selectively formed during formation of the supported capacitor electrode structure 200.

The inner layer 235 may be a semiconductor and may comprise, consist of, or consist essentially of semiconductive material. The semiconductive material may comprise, consist of, or consist essentially of titanium silicon nitride. Alternatively, the semiconductive material may comprise, consist of, or consist essentially of silicon (e.g., polycrystalline silicon), a type III-V element, or another suitable semiconductive material, among other examples. In some implementations, and as described in greater detail in connection with FIGS. 3-4G, the inner layer 235 may be remains of a sacrificial layer that is used during formation of the supported capacitor electrode structure 200.

In practice, a material for one or more features of the supported capacitor electrode structure 200 may be determined based on selectivity properties associated with techniques described in connection with FIGS. 3-4G used to form the supported capacitor electrode structure 200. Furthermore, the materials described above are by way of example only, and other materials that may be included in features of the supported capacitor electrode structure 200 are within the scope of the present disclosure.

The supported capacitor electrode structure 200 may include different geometric and/or dimensional properties. As an example, and as shown in FIG. 2, the outer layer 230 may include a curved surface along an interface between the outer layer 230 and the inner layer 235. Additionally, or alternatively and in some implementations, the outer layer 230 includes at least a portion that extends outwardly relative to an outer perimeter 240 of the of the pillar structure 205.

As another example, and as shown in FIG. 2, the inner layer 235 may have a curved surface along an interface between the inner layer 235 and pillar structure 205. Additionally, or alternatively and in some implementations, the inner layer 235 includes at least a portion that extends inwardly relative to the outer perimeter 240 of the pillar structure 205.

As another example, and as shown in FIG. 2, a vertical length L1 of the outer layer 230 along an interface between the outer layer 230 and the inner layer 235 may be less than an overall vertical length L2 of the inner layer 235. Additionally, or alternatively and in some implementations, a thickness T1 of the inner layer 235 is greater than a thickness T2 of the outer layer 230. Additionally, or alternatively and in some implementations, a width W1 of the pillar structure 205 directly adjacent to the inner layer 235 is less than a width W2 of the pillar structure 205 at a distal end of the pillar structure 205.

In practice, a geometric and/or a dimensional property of one or more features of the supported capacitor electrode structure 200 may be determined based on selectivity properties associated with techniques described in connection with FIGS. 3-4G that form the supported capacitor electrode structure 200. Furthermore, the geometric and/or dimensional properties described above are by way of example only, and other geometric and/or dimensional properties that may be associated with features of the supported capacitor electrode structure 200 are within the scope of the present disclosure.

As indicated above, FIG. 2 is provided as an example. Other examples may differ from what is described with respect to FIG. 2. In practice, there may be additional components and/or layers, fewer components and/or layers, different components and/or layers, or differently arranged components and/or layers than those shown in FIG. 2.

As described in connection with FIG. 1 and FIG. 2, and in some implementations, an integrated assembly includes a support layer (e.g., the support layer 220) of a dielectric material and a pillar structure (e.g., the pillar structure 205) of a conductive material passing through the support layer. The integrated assembly includes a multi-layer coupling structure (e.g., the multi-layer coupling structure 225) between the pillar structure and the support layer that conjoins the pillar structure with the support layer. The multi-layer coupling structure includes an outer layer (e.g., the outer layer 230) that conjoins with the support layer and an inner layer (e.g., the inner layer 235) that conjoins with the pillar structure. In some implementations, the outer layer and the inner layer include respective materials that are different from each other.

Additionally, or alternatively and in some implementations, an apparatus includes a memory cell (e.g., the memory cell 100). The memory cell includes a supported capacitor electrode structure (e.g., the supported capacitor electrode structure 200). The supported capacitor electrode structure 200 includes a support layer (e.g., the support layer 220) that is laterally-oriented, a pillar structure (e.g., the pillar structure 205) that is vertically-oriented, and a multi-layer coupling structure (e.g., the multi-layer coupling structure 225) between the pillar structure and the support layer that conjoins the pillar structure and the support layer. The multi-layer coupling structure includes an inner layer (e.g., the inner layer 235) having at least a portion that extends inwardly relative to an outer perimeter (e.g., the outer perimeter 240) of the vertically-oriented pillar structure, and an outer layer (e.g., the outer layer 230) having at least a portion that extends outwardly relative to the outer perimeter of the vertically-oriented pillar structure.

In these ways, a structural integrity and manufacturing efficiency of a memory cell including the integrated assembly and/or the apparatus are enhanced. The supported capacitor electrode structure using the multi-layer coupling structure may reduce a risk of detachment between the pillar structure and the support layer, thereby mitigating risks of short-circuiting and improving operational reliability of the memory cell, resulting in optimal resource utilization and contributing to the conservation of processing resources and raw materials. Additionally, the supported capacitor electrode structure using the multi-layer coupling structure serves to decrease a likelihood of structural weakness during sculpting of the pillar structure to its final dimensions, ultimately contributing to lower defect rates and higher throughput in semiconductor fabrication.

FIG. 3 is a flowchart of an example method 300 of forming an integrated assembly or memory device having a supported capacitor electrode structure described herein (e.g., the supported capacitor electrode structure 200). In some implementations one or more method blocks of FIG. 3 may be performed by various semiconductor manufacturing equipment.

As shown in FIG. 3, the method 300 may include receiving a partially-formed memory array structure including a layer stack having a mid-lattice layer (e.g., the support layer 220) between two molding layers (block 310). As further shown in FIG. 3, the method 300 may include forming a cavity through the layer stack (block 320). As further shown in FIG. 3, the method 300 may include forming a protective layer (e.g., the outer layer 230) on a surface of the mid-lattice layer exposed by the cavity (block 330). As further shown in FIG. 3, the method 300 may include forming a sacrificial layer (e.g., the inner layer 235) in the cavity on the protective layer (block 340). As further shown in FIG. 3, the method 300 may include forming a conductive layer (e.g., the pillar structure 205) in the cavity on the sacrificial layer (block 350). As further shown in FIG. 3, the method 300 may include removing the two molding layers (block 360). As further shown in FIG. 3, the method 300 may include removing portions of the sacrificial layer to reveal a multi-layer coupling structure (e.g., the multi-layer coupling structure 225) that conjoins the conductive layer with the mid-lattice layer (block 370).

The method 300 may include additional aspects, such as any single aspect or any combination of aspects described below and/or in connection with one or more other methods described elsewhere herein.

In a first aspect, forming the protective layer includes forming the protective layer using a selective deposition process that excludes forming the protective layer on surfaces of the two molding layers exposed by the cavity.

In a second aspect, alone or in combination with the first aspect, the selective deposition process includes depositing the protective layer using an atomic layer deposition technique.

In a third aspect, alone or in combination with one or more of the first and second aspects, the selective deposition process includes applying an inhibitor that selectively adheres to surfaces of the two molding layers to prevent the protective layer from forming on the surfaces.

In a fourth aspect, alone or in combination with one or more of the first through third aspects, the selective deposition process includes applying a precursor to the surface of the mid-lattice layer that promotes formation of the protective layer on the surface.

In a fifth aspect, alone or in combination with one or more of the first through fourth aspects, forming the conductive layer includes forming the conductive layer along a contour of the sacrificial layer that protrudes into the cavity.

In a sixth aspect, alone or in combination with one or more of the first through fifth aspects, removing the portions of the sacrificial layer includes removing portions of the sacrificial layer along surfaces of the two molding layers.

In a seventh aspect, alone or in combination with one or more of the first through sixth aspects, removing the portions of the sacrificial layer includes removing portions of the sacrificial layer to form cavities that reduce a length of an interface between the sacrificial layer and the protective layer.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the supported capacitor electrode structure 200, an integrated assembly that includes the supported capacitor electrode structure 200, any part described herein of supported capacitor electrode structure 200, and/or any part described herein of an integrated assembly that includes the supported capacitor electrode structure 200. For example, the method 300 may include forming one or more parts of the memory cell 100.

FIGS. 4A-4G are diagrammatic views showing a supported capacitor electrode structure 200 at example stages of an example process 400 of forming the supported capacitor electrode structure 200. In some implementations, the process 400 described below in connection with FIGS. 4A-4G may correspond to the method 300 and/or one or more blocks of the method 300. However, the process 400 described below is an example, and other example processes may be used to form the supported capacitor electrode structure 200, an integrated assembly that includes the supported capacitor electrode structure 200, and/or one or more parts of the supported capacitor electrode structure 200 and/or the integrated assembly.

As shown in FIG. 4A, the process 400 may include receiving a layer stack. As shown in FIG. 4A, the layer stack includes the support layer 220 (e.g., a mid-lattice layer) between two molding layers 405. Each of the two molding layers 405 may include silicon dioxide or another suitable dielectric material that is different from a material of the mid-lattice layer. In some implementations, the layer stack may correspond to a layer stack of a partially formed memory array structure.

As shown in FIG. 4B, the process 400 may include forming cavities 410 in the layer stack. Forming the cavities 410 may include removing (e.g., etching) portions of the two molding layers 405 and the support layer 220. In some implementations, one or more masks may be used to form the cavities 410. For example, one or more masks may be deposited and/or patterned over and/or on the layer stack prior to removing the portions of the two molding layers 405 and the support layer 220 to form the cavities 410.

As shown in FIG. 4C, the process 400 may include forming (e.g., depositing, growing) the outer layer 230 (e.g., a protective layer) over and/or on surfaces of the support layer 220 exposed by the cavities 410. Forming the outer layer 230 may include using a selective deposition process to form the outer layer 230 over and/or on the surfaces.

As an example, the selective deposition process may include applying an inhibitor that selectively adheres to surfaces of two molding layers 405 that are exposed by the cavities 410, but does not adhere to the surfaces of the support layer 220 exposed by the cavities 410. In a case where the two molding layers 405 include silicon dioxide, the support layer 220 includes silicon nitride, and the outer layer 230 includes titanium nitride, for example, the inhibitor may be an organic silane compound such as hexamethyldisilazane.

After deposition of the inhibitor, formation of the outer layer 230 may occur over and/or on exposed surfaces of the support layer 220 while being excluded from occurring over and/or on exposed surfaces of the two molding layers 405. After formation of the outer layer 230, the inhibitor may be removed from the surfaces of the two molding layers 405 using a solvent rinsing technique, a plasma cleaning technique, a wet chemical etching technique, or another suitable removal technique.

Additionally, or alternatively, the selective deposition process may include applying a precursor that selectively adheres to surfaces of the support layer 220 and promotes growth of the outer layer 230 over and/or on the surfaces of the support layer 220. Selectively adhering to the surfaces of the support layer 220 may be indicative of the precursor having a strong affinity or chemical compatibility with molecules of the support layer 220 (e.g., silicon nitride molecules) and a lesser affinity or chemical compatibility with molecules of the two molding layers 405 (e.g., silicon dioxide molecules). In a case where the two molding layers 405 include silicon dioxide, the support layer 220 includes silicon nitride, and the outer layer 230 includes titanium nitride, for example, the precursor may include titanium tetrachloride.

As shown in FIG. 4D, the process 400 may include forming (e.g., depositing, growing) the inner layer 235 (e.g., a sacrificial layer) in the cavities 410 over and/or on surfaces of the two molding layers 405 and over and/or on the outer layer 230. In some implementations, and as shown in FIG. 4E, the inner layer 235 may include contours 415 that protrude into the cavities 410.

As shown in FIG. 4E, the process 400 may include forming (e.g., depositing, growing) the pillar structure 205 (e.g., a conductive layer) over and/or on the inner layer 235. In some implementations, and as shown in FIG. 4E, at least a portion of the conductive layer is formed along the contours 415.

As shown in FIG. 4F, the process 400 may include removing (e.g., etching) the two molding layers 405. Furthermore, and as shown in FIG. 4F, the process 400 may include removing (e.g., etching) portions of the inner layer 235 to reveal the multi-layer coupling structure 225. In some implementations, and as shown in FIG. 4F, removing the portions of the inner layer 235 may form cavities 420 that reduce a length of an interface between the inner layer 235 and the outer layer 230. Formation of the cavities 420 may be resultant of an increased length of an etch path around the outer layer 230 that inhibits removal of the inner layer 235 between outer layer 230 and the pillar structure 205, thereby reducing a likelihood of the multi-layer coupling structure 225 from detaching from the pillar structure 205.

As shown in FIG. 4G, the process 400 may include forming (e.g., depositing, growing) the insulator layer 215 over and/or on the support layer 220 and the pillar structure 205. Furthermore, and as shown in FIG. 4G, the process 400 may include forming (e.g., depositing, growing) the conductive layer 210 over and/or on the insulator layer 215. Formation of the insulator layer 215 and the conductive layer 210 may form the supported capacitor electrode structure 200 (including the capacitor 110).

As indicated above, the process steps described in connection with FIGS. 4A-4G are provided as examples. Other examples may differ from what is described with respect to FIGS. 4A-4G. The structure shown in FIGS. 4A-4G may be equivalent to the supported capacitor electrode structure 200 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

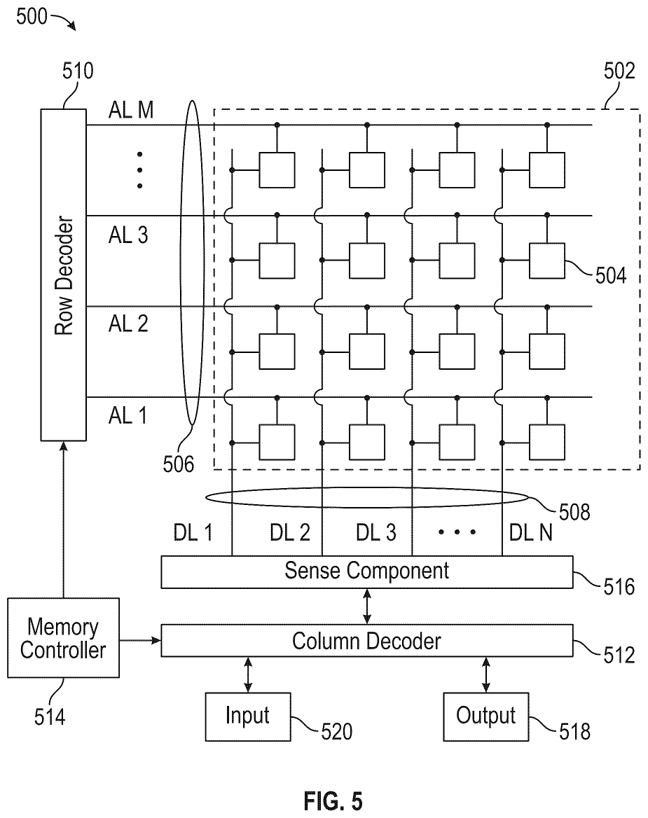

FIG. 5 is a diagrammatic view of an example memory device 500. The memory device 500 may include a memory array 502 that includes multiple memory cells 504. A memory cell 504 is programmable or configurable into a data state of multiple data states (e.g., two or more data states). For example, a memory cell 504 may be set to a particular data state at a particular time, and the memory cell 504 may be set to another data state at another time. A data state may correspond to a value stored by the memory cell 504. The value may be a binary value, such as a binary 0 or a binary 1, or may be a fractional value, such as 0.5, 1.5, or the like. A memory cell 504 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 504 by activating or selecting the appropriate access line 506 (shown as access lines AL 1 through AL M) and digit line 508 (shown as digit lines DL 1 through DL N). An access line 506 may also be referred to as a “row line” or a “word line,” and a digit line 508 may also be referred to a “column line” or a “bit line.” Activating or selecting an access line 506 or a digit line 508 may include applying a voltage to the respective line. An access line 506 and/or a digit line 508 may comprise, consist of, or consist essentially of a conductive material, such as a metal (e.g., copper, aluminum, gold, titanium, or tungsten) and/or a metal alloy, among other examples. In FIG. 5, each row of memory cells 504 is connected to a single access line 506, and each column of memory cells 504 is connected to a single digit line 508. By activating one access line 506 and one digit line 508 (e.g., applying a voltage to the access line 506 and digit line 508), a single memory cell 504 may be accessed at (e.g., is accessible via) the intersection of the access line 506 and the digit line 508. The intersection of the access line 506 and the digit line 508 may be called an “address” of a memory cell 504.

In some implementations, the logic storing device of a memory cell 504, such as a capacitor, may be electrically isolated from a corresponding digit line 508 by a selection component, such as a transistor. The access line 506 may be connected to and may control the selection component. For example, the selection component may be a transistor, and the access line 506 may be connected to the gate of the transistor. Activating the access line 506 results in an electrical connection or closed circuit between the capacitor of a memory cell 504 and a corresponding digit line 508. The digit line 508 may then be accessed (e.g., is accessible) to either read from or write to the memory cell 504.

A row decoder 510 and a column decoder 512 may control access to memory cells 504. For example, the row decoder 510 may receive a row address from a memory controller 514 and may activate the appropriate access line 506 based on the received row address. Similarly, the column decoder 512 may receive a column address from the memory controller 514 and may activate the appropriate digit line 508 based on the column address.

Upon accessing a memory cell 504, the memory cell 504 may be read (e.g., sensed) by a sense component 516 to determine the stored data state of the memory cell 504. For example, after accessing the memory cell 504, the capacitor of the memory cell 504 may discharge onto its corresponding digit line 508. Discharging the capacitor may be based on biasing, or applying a voltage, to the capacitor. The discharging may induce a change in the voltage of the digit line 508, which the sense component 516 may compare to a reference voltage (not shown) to determine the stored data state of the memory cell 504. For example, if the digit line 508 has a higher voltage than the reference voltage, then the sense component 516 may determine that the stored data state of the memory cell 504 corresponds to a first value, such as a binary 1.

Conversely, if the digit line 508 has a lower voltage than the reference voltage, then the sense component 516 may determine that the stored data state of the memory cell 504 corresponds to a second value, such as a binary 0. The detected data state of the memory cell 504 may then be output (e.g., via the column decoder 512) to an output component 518 (e.g., a data buffer). A memory cell 504 may be written (e.g., set) by activating the appropriate access line 506 and digit line 508. The column decoder 512 may receive data, such as input from input component 520, to be written to one or more memory cells 504. A memory cell 504 may be written by applying a voltage across the capacitor of the memory cell 504.

The memory controller 514 may control the operation (e.g., read, write, re-write, refresh, and/or recovery) of the memory cells 504 via the row decoder 510, the column decoder 512, and/or the sense component 516. The memory controller 514 may generate row address signals and column address signals to activate the desired access line 506 and digit line 508. The memory controller 514 may also generate and control various voltages used during the operation of the memory array 502.

In some implementations, the memory device 500 includes the supported capacitor electrode structure 200, and/or an integrated assembly that includes the supported capacitor electrode structure 200. For example, the memory array 502 may include the supported capacitor electrode structure 200, and/or an integrated assembly that supported capacitor electrode structure 200. Additionally, or alternatively, the memory cell 504 may include a memory cell described elsewhere herein.

As indicated above, FIG. 5 is provided as an example. Other examples may differ from what is described with respect to FIG. 5.

In some implementations, an integrated assembly includes a support layer, comprising: a dielectric material; a pillar structure passing through the support layer, comprising: a conductive material; and a multi-layer coupling structure between the pillar structure and the support layer that conjoins the pillar structure with the support layer, comprising: an outer layer that conjoins with the support layer; and an inner layer that conjoins with the pillar structure, where the inner layer and the outer layer comprise respective materials that are different from each other.

In some implementations, an apparatus includes a memory cell, comprising: a supported capacitor electrode structure, comprising: a laterally-oriented support layer; a vertically-oriented pillar structure; and a multi-layer coupling structure between the vertically-oriented pillar structure and the laterally-oriented support layer that conjoins the vertically-oriented pillar structure and the laterally-oriented support layer, comprising: an inner layer having at least a portion that extends inwardly relative to an outer perimeter of the vertically-oriented pillar structure, and an outer layer having at least a portion that extends outwardly relative to the outer perimeter of the vertically-oriented pillar structure.

In some implementations, a method includes receiving a partially-formed memory array structure including a layer stack having a mid-lattice layer between two molding layers; forming a cavity through the layer stack; forming protective layer on a surface of the mid-lattice layer exposed by the cavity, forming a sacrificial layer in the cavity on the protective layer; forming a conductive layer in the cavity on the sacrificial layer; removing the two molding layers; and removing portions of the sacrificial layer to reveal a multi-layer coupling structure that conjoins the conductive layer with the mid-lattice layer.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a support layer, comprising:
a dielectric material;
a pillar structure passing through the support layer, comprising:
a conductive material; and
a multi-layer coupling structure between the pillar structure and the support layer that conjoins the pillar structure with the support layer, comprising:
an outer layer that conjoins with the support layer; and
an inner layer that conjoins with the pillar structure,
wherein the inner layer and the outer layer comprise respective materials that are different from each other.

2. The integrated assembly of claim 1, wherein the dielectric material comprises:
silicon nitride.

3. The integrated assembly of claim 1, wherein the pillar structure comprises titanium nitride.

4. The integrated assembly of claim 1, wherein the dielectric material comprises an anti-ferroelectric material.

5. The integrated assembly of claim 1, wherein the inner layer and the outer layer conjoin with each other.

6. The integrated assembly of claim 1, wherein the inner layer comprises titanium silicon nitride.

7. An apparatus, comprising:
a memory cell, comprising:
a supported capacitor electrode structure, comprising:
a laterally-oriented support layer;
a vertically-oriented pillar structure; and
a multi-layer coupling structure between the vertically-oriented pillar structure and the laterally-oriented support layer that conjoins the vertically-oriented pillar structure and the laterally-oriented support layer, comprising:
an inner layer having at least a portion that extends inwardly relative to an outer perimeter of the vertically-oriented pillar structure, and
an outer layer having at least a portion that extends outwardly relative to the outer perimeter of the vertically-oriented pillar structure.

8. The apparatus of claim 7, wherein a width of the vertically-oriented pillar structure directly adjacent to the inner layer is less than a width of the vertically-oriented pillar structure at a distal end of the vertically-oriented pillar structure.

9. The apparatus of claim 7, wherein a vertical length of the outer layer along an interface between the outer layer and the inner layer is less than an overall vertical length of the inner layer.

10. The apparatus of claim 7, wherein a thickness of the inner layer is greater than a thickness of the outer layer.

11. The apparatus of claim 7, wherein the inner layer comprises:
a curved surface along an interface between the inner layer and the vertically-oriented pillar structure.

12. The apparatus of claim 7, wherein the outer layer comprises:
a curved surface along an interface between the outer layer and the inner layer.

13. A method, comprising:
receiving a partially-formed memory array structure including a layer stack having a mid-lattice layer between two molding layers;
forming a cavity through the layer stack;
forming a protective layer on a surface of the mid-lattice layer exposed by the cavity, forming a sacrificial layer in the cavity on the protective layer;
forming a conductive layer in the cavity on the sacrificial layer;
removing the two molding layers; and
removing portions of the sacrificial layer to reveal a multi-layer coupling structure that conjoins the conductive layer with the mid-lattice layer.

14. The method of claim 13, wherein forming the protective layer includes:
forming the protective layer using a selective deposition process that excludes forming the protective layer on surfaces of the two molding layers exposed by the cavity.

15. The method of claim 14, wherein the selective deposition process includes:
depositing the protective layer using an atomic layer deposition technique.

16. The method of claim 14, wherein the selective deposition process includes:
applying an inhibitor that selectively adheres to surfaces of the two molding layers to prevent the protective layer from forming on the surfaces.

17. The method of claim 14, wherein the selective deposition process includes:
applying a precursor to the surface of the mid-lattice layer that promotes formation of the protective layer on the surface.

18. The method of claim 13, wherein forming the conductive layer includes:
forming the conductive layer along a contour of the sacrificial layer that protrudes into the cavity.

19. The method of claim 13, wherein removing the portions of the sacrificial layer includes:
removing portions of the sacrificial layer along surfaces of the two molding layers.

20. The method of claim 13, wherein removing the portions of the sacrificial layer includes:
removing portions of the sacrificial layer to form cavities that reduce a length of an interface between the sacrificial layer and the protective layer.
